(19) United States
(12) Patent Application Publication
(10) Pub. No.: US 2015/0200238 A1
(43) Pub. Date: Jul. 16, 2015

(54) THIN FILM TRANSISTOR, METHOD OF MANUFACTURING THE THIN FILM TRANSISTOR AND FLAT PANEL DISPLAY DEVICE HAVING THE THIN FILM TRANSISTOR

(71) Applicant: SAMSUNG DISPLAY CO., LTD., Yongin-City (KR)

(72) Inventors: Moo-Soon KO, Yongin-City (KR); IL-Jeong LEE, Yongin-City (KR)

(21) Appl. No.: 14/573,565

(22) Filed: Dec. 17, 2014

(30) Foreign Application Priority Data
Jan. 13, 2014 (KR) 10-2014-0003822

(51) Int. Cl. H01L 27/32; H01L 21/28; H01L 21/311; H01L 29/786; H01L 29/66

(52) U.S. Cl. CPC H01L 27/3258; H01L 29/78666; H01L 29/66757; H01L 21/31127; H01L 21/31144; H01L 21/28132

(57) ABSTRACT

A thin film transistor (TFT) includes a substrate, a semiconductor pattern on the substrate, the semiconductor pattern including an active region, and source and drain regions opposite to each other at respective sides of the active region, a first insulating layer on the active region, a gate electrode on the first insulating layer, the gate electrode overlapping the active region, a second insulating layer on a front surface of the substrate having the gate electrode formed thereon, the second insulating layer including contact holes through which portions of the respective source and drain regions are exposed, and source and drain electrodes formed on the second insulating layer, the source and drain electrodes being respectively coupled to the source and drain regions through the contact holes.

### CROSS-REFERENCE TO RELATED APPLICATION

Korean Patent Application No. 10-2014-0003822, filed on Jan. 13, 2014, in the Korean Intellectual Property Office, and entitled: “Thin Film Transistor, Method of Manufacturing the Thin Film Transistor and Flat Panel Display Device Having the Thin Film Transistor,” is incorporated by reference herein in its entirety.

### BACKGROUND

1. Field

Embodiments relate to a thin film transistor (TFT), a method of manufacturing the TFT and a flat panel display device having the TFT.

2. Description of the Related Art

A thin film transistor (TFT) is used in various electronic devices including a flat panel display device, and the like. For example, the TFT is used as a switching element or driving element in flat panel display devices including a liquid crystal display (LCD), an organic light emitting diode (OLED) display, an electrophoretic display, and the like.

### SUMMARY

Embodiments are directed to a thin film transistor (TFT) including a substrate, a semiconductor pattern on the substrate, the semiconductor pattern including an active region, and source and drain regions opposite to each other at respective sides of the active region, a first insulating layer on the active region, a gate electrode on the first insulating layer, the gate electrode overlapping the active region, a second insulating layer on a front surface of the substrate having the gate electrode formed thereon, the second insulating layer including contact holes through which portions of the respective source and drain regions are exposed, and source and drain electrodes formed on the second insulating layer, the source and drain electrodes being respectively coupled to the source and drain regions through the contact holes.

The second insulating layer may include an organic insulating material.

The first insulating layer and the gate electrode may have a same planar area, and may completely overlap each other.

The first and second insulating layers may include different materials from each other.

The first insulating layer may include an inorganic insulating material.

Embodiments are also directed to a method of manufacturing a TFT including providing a substrate, forming, on the substrate, a semiconductor pattern including an active region, and source and drain regions opposite to each other at respective sides of the active region, forming a first insulating layer and a gate electrode to overlap the active region, depositing an organic insulating material layer on a front surface of the substrate having the gate electrode formed thereon, providing a mask above the substrate having the organic insulating material layer formed thereon, forming a second insulating layer by patterning the organic insulating material layer to include contact holes through which portions of the respective source and drain regions are exposed, using the mask, and forming source and drain electrodes respectively coupled to the source and drain regions through the contact holes.

Forming the first insulating layer and the gate electrode may further include forming an insulating material layer on the semiconductor pattern, depositing a metal layer on the insulating material layer, forming the gate electrode by patterning the metal layer to overlap the active region, and forming the first insulating layer by removing the insulating material layer except for a portion that overlaps with the gate electrode, using the gate electrode as an etch mask.

The first insulating layer and the gate electrode may have a same planar area, and completely overlap each other.

The first and second insulating layers may include different materials from each other.

The first insulating layer may include an inorganic insulating material.

Embodiments are also directed to a flat panel display device including a first substrate on which an organic light emitting diode including a first electrode, an organic emission layer and a second electrode, and a TFT for controlling an operation of the organic light emitting diode are located, and a second substrate opposite to the first substrate. The TFT includes a semiconductor pattern on the first substrate, the semiconductor pattern including an active region, and source and drain regions opposite to each other at respective sides of the active region, a first insulating layer on the active region, a gate electrode on the first insulating layer, the gate electrode overlapping the active region, a second insulating layer on a front surface of the first substrate having the gate electrode formed thereon, the second insulating layer including first contact holes through which portions of the respective source and drain regions are exposed, source and drain electrodes on the second insulating layer, the source and drain electrodes being respectively coupled to the source and drain regions through the first contact holes, and a third insulating layer on the source and drain electrodes, the third insulating layer including a second contact hole through which a portion of the drain electrode is exposed. The drain electrode and the first electrode are electrically coupled to each other through the second contact hole.

The second insulating layer may include an organic insulating material.

The first insulating layer and the gate electrode may have a same planar area, and may completely overlap each other.

The first and second insulating layers may include different materials from each other.

The first insulating layer may include an inorganic insulating material.

The third insulating layer may be made of at least one selected from an inorganic insulating material and an organic insulating material.

### BRIEF DESCRIPTION OF THE DRAWINGS

Features will become apparent to those of ordinary skill in the art by describing in detail exemplary embodiments with reference to the attached drawings in which:

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration.

It will be understood that when an element is referred to as being “between” two elements, it can be the only element between the two elements, or one or more intervening elements may also be present. Like reference numerals refer to like elements throughout.

FIG. 1 illustrates a sectional view depicting a thin film transistor (TFT) according to an embodiment.

FIGS. 2 to 8 illustrate sectional views sequentially depicting stages of a method of manufacturing the TFT of FIG. 1 according to the embodiment.

FIG. 9 illustrates a sectional view schematically depicting a flat panel display device including the TFT according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

When a first element is described as being coupled to a second element, the first element may be not only directly coupled to the second element but may also be indirectly coupled to the second element via a third element. Further, some of the elements that are not essential to the complete understanding of the invention are omitted for clarity.

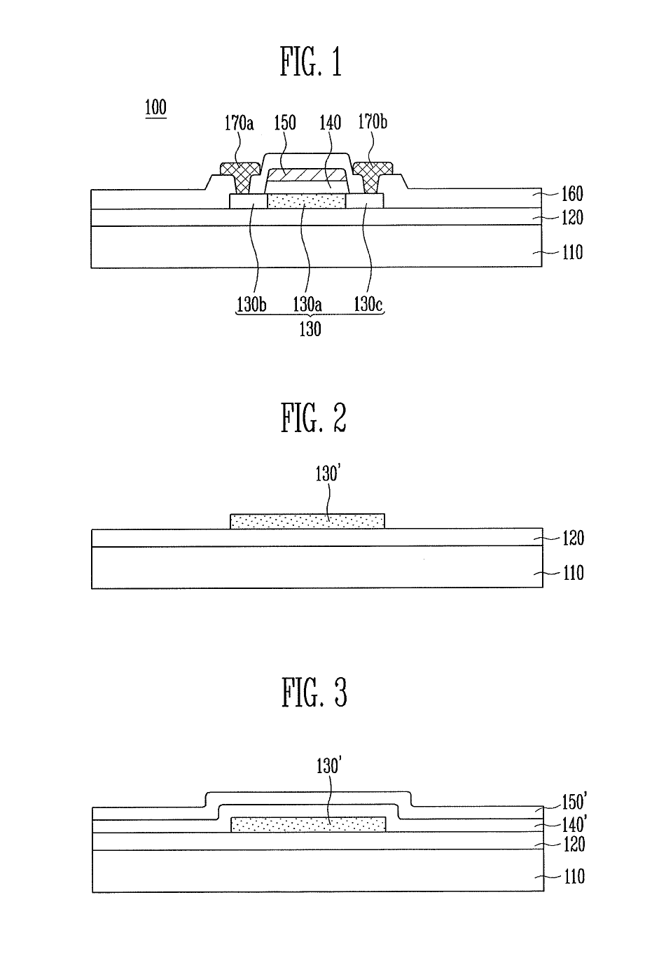

FIG. 1 illustrates a sectional view depicting a thin film transistor (TFT) according to an embodiment.

Referring to FIG. 1, the TFT 100 according to this embodiment includes a substrate 110, a buffer layer 120 formed on the substrate 110, a semiconductor pattern 130 formed on the buffer layer 120, a first insulating layer 140 formed on the semiconductor pattern 130, a gate electrode 150 formed on the first insulating layer 140, a second insulating layer 160 formed on the gate electrode 150, and source and drain electrodes 170a and 170b formed on the second insulating layer 160.

The substrate 110 may be appropriately selected from a transparent substrate such as glass, a quartz substrate, a ceramic substrate, a silicon substrate, a flexible substrate such as plastic, or the like, according to tan intended use. For example, in case of a bottom emission type substrate, the substrate 110 may be formed of a transparent material.

The buffer layer 120 may be formed on a front surface of the substrate 110. The buffer layer 120 may perform a function of protecting the semiconductor pattern 130 formed in a subsequent process from the penetration of impurities such as alkali ions, which may be discharged from the substrate 110, and may perform a function of planarizing the surface of the substrate 110. The material of the buffer layer 120 may be a suitable material that performs these functions. The buffer layer 120 may be formed using an ordinary method such as chemical vapor deposition, etc. The buffer layer 120 may be omitted according to the kind and process conditions of the substrate 110.

The semiconductor pattern 130 may be formed on the buffer layer 120. The semiconductor pattern 130 may include an active region 130a into which impurities are not injected, and source and drain regions 130b and 130c formed by injecting p-type or n-type impurities into respective sides of the active region 130a. The impurities may be selected depending on the kind of TFT.

The semiconductor pattern 130 may be formed by injecting impurities into a semiconductor layer. The semiconductor pattern 130 may be formed of amorphous silicon, multi-crystalline silicon or the like. When the semiconductor pattern 130 is formed of multi-crystalline silicon, it may be possible to obtain an electric charge mobility higher than that when the semiconductor pattern 130 is formed of the amorphous silicon. The semiconductor pattern 130 formed of the multi-crystalline silicon may be formed by directly depositing the multi-crystalline silicon on the buffer layer 120, or may be formed by forming an amorphous silicon layer and then crystallizing and patterning the amorphous silicon layer, using excimer laser annealing (ELA), sequential lateral solidification (SLS), metal induced crystallization (MIC), metal induced lateral crystallization (MILC), super grain silicon (SGS) crystallization, etc.

The first insulating layer 140 may be formed on the semiconductor pattern 130 at only a portion corresponding to the active region 130a. The first insulating layer 140 may include, for example, an inorganic insulating material having a single layer configured with one kind of layer selected from silicon oxide (SiO₂), silicon nitride (SiN) and silicon oxynitride (SiON), or a stacked layer configured with two or more kinds of layers selected from silicon oxide (SiO₂), silicon nitride (SiN) and silicon oxynitride (SiON).

The gate electrode 150 may be formed on the first insulating layer 140 at a portion that overlaps with the active region 130a of the semiconductor pattern 130. The boundary of a side portion of the gate electrode 150 and the boundary of a side portion of the first insulating layer 140 may be aligned to substantially correspond to each other. The gate electrode 150 and the first insulating layer 140 may have the same planar area, and may completely overlap with each other.

The active region 130a of the semiconductor pattern 130 may overlap with the first insulating layer 140 and the gate electrode 150, which are sequentially formed.

The gate electrode 150 may be formed as a single-layered structure with a single material or a mixture selected from the group consisting of molybdenum (Mo), tungsten (W), aluminum neodymium (AlNd), titanium (Ti), aluminum (Al), silver (Ag) and alloy thereof. The gate electrode may be formed into a double- or multi-layered structure with Mo, Al, or Ag, which is a low-resistance material, in order to reduce wire resistance. The gate electrode 150 may be formed by sequentially laminating conductive layers of a multi-layered structure in order to reduce the wire resistance. The gate electrode 150 may have a multi-layered structure including Mo/Al/Mo, MoW/AlNd/MoW, Mo/Ag/Mo, Mo/Ag alloy/Mo, or Ti/Al/Mo.

The first insulating layer 140 may be removed from the substrate 110 through an etching process using the gate electrode 150 as an etch mask after the gate electrode 150 is formed. That is, the first insulating layer 140 may be formed below only the gate electrode 150 and may not be present on the source and drain regions 130b and 130c of the semiconductor pattern 130.

The second insulating layer 160 may be formed with an organic insulating layer having a photosensitive characteristic, and may include contact holes through which portions of the source and drain regions 130b and 130c are exposed on the substrate 110. The second insulating layer 160 may directly contact the source and drain regions 130b and 130c from which the first insulating layer 140 is removed.

The organic insulating layer may include, for example, a general purpose compound (for example, PMMA, PS), a polymer derivative including a phenol group, a acryl-based polymer, an imide-based polymer, an aryl ether-based, an amide-based polymer, a fluorine-based polymer, a p-xylene-based polymer, a vinyl alcohol-based polymer, a blend thereof, or the like.

The second insulating layer 160 may be formed with the organic insulating layer having the photosensitive characteristic. Accordingly, the second insulating layer 160 may be patterned to include the contact holes through which the source and drain regions 130b and 130c are exposed through only a photo process using a mask.

The second insulating layer 160 may be formed through the photo process. The second insulating layer 160 may not cause a reaction with an etching gas used in a dry etching process. The roughness of the surface of the second insulating layer 160 may be minimized, such that the organic insulating layer may be easily applied to the TFT 100.

The surface roughness of the second insulating layer 160 may be minimized.

The second insulating layer 160 may have no influence on the shapes of the source and drain electrodes 170a and 170b formed on the second insulating layer 160 through a subsequent process, thereby implementing the low resistance of metal. Further, the second insulating layer 160 may have a low dielectric constant. Parasitic capacitance between the electrodes may be minimized, thereby improving characteristics of the TFT 100.

The source and drain electrodes 170a and 170b may be formed on the second insulating layer 160. The source and drain electrodes 170a and 170b may be coupled to the source and drain regions 130b and 130c through the contact holes, respectively.

The source and drain electrodes 170a and 170b may be formed as a single-layered structure with a single material or a mixture selected from the group of Mo, W, AlNd, Ti, Al, Ag and alloys thereof, or may be formed as a double- or multi-layered structure with Mo, Al or Ag, which is a low-resistance material, in order to reduce wire resistance.

As described above, in the TFT 100 according to this embodiment, the surface roughness of the second insulating layer 160 formed with the organic insulating layer may be minimized. The metal resistance of the source and drain electrodes 170a and 170b formed through a subsequent process may be minimized, thereby improving characteristics of the TFT 100.

Further, in the TFT 100 according to this embodiment, the source and drain regions 130b and 130c may be exposed by removing the first insulating layer 140 except for a portion positioned below the gate electrode 150 when the gate electrode 150 is formed. The second insulating layer 160 may be directly formed on the source and drain regions 130b and 130c through the photo process, so that it may be possible to omit an etching process for forming contact holes.

Accordingly, it may be possible to simplify a manufacturing process of the TFT 100 according to this embodiment.

Hereinafter, a manufacturing method of an array substrate including the TFT according to this embodiment will be described in detail.

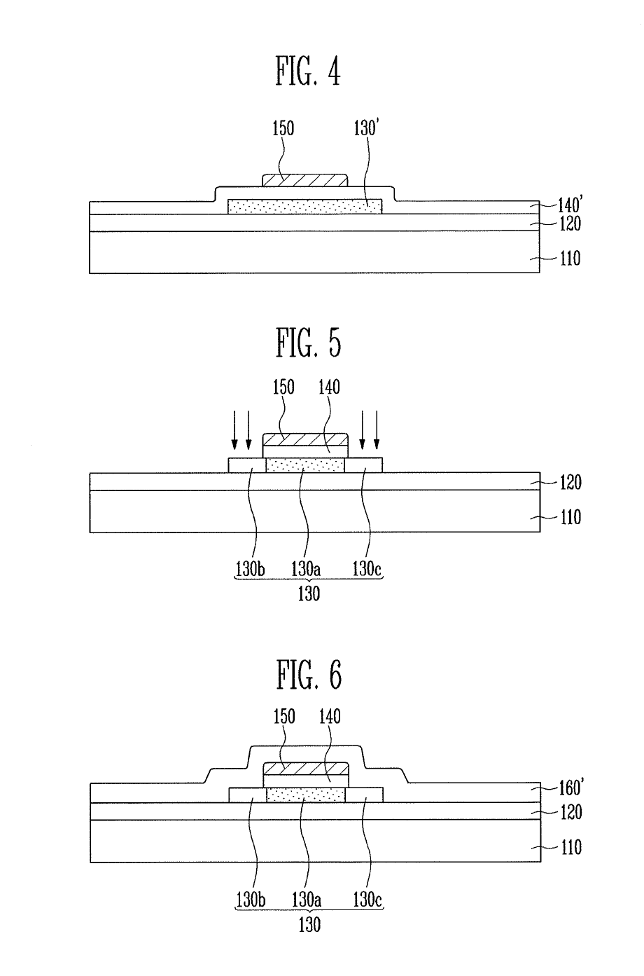

FIGS. 2 to 8 illustrate sectional views sequentially depicting stages of a method of manufacturing the TFT of FIG. 1 according to the embodiment.

Referring to FIG. 2, a buffer layer 120 may be formed on a substrate 110 made of glass, plastic, etc. through chemical vapor deposition, plasma enhanced chemical vapor deposition, or the like. The buffer layer 120 may be made of an insulating material including an oxide, such as silicon oxide (SiOₓ), aluminum oxide (Al₂O₃), hafnium oxide (HfO₃) or yttrium oxide (Y₂O₃).

A semiconductor material layer 130′ may be deposited on a front surface of the substrate 110 having the buffer layer 120 formed thereon. A photosensitive pattern (not shown) may be formed by applying a photosensitive layer such as a photoresist on the semiconductor material layer 130′ and light-exposing the applied photosensitive layer. The semiconductor material layer 130′ may be patterned to remain in only a specific region of the buffer layer 120, using the photosensitive pattern as a mask.

Referring to FIG. 3, an insulating material layer 140′ may be formed on the substrate 110 having the semiconductor material layer 130′ formed thereon. The insulating material layer 140′ may be formed as a single layer including an insulative oxide such as silicon oxide (SiOₓ), or may be formed with multiple layers configured with a lower layer including an insulative material such as silicon oxide (SiOₓ) and an upper layer including another insulating material.

A conductive material layer 150′ made of metal or the like may be laminated on the substrate 110 having the insulating material layer 140′.

Referring to FIG. 4, a gate electrode 150 may be formed by patterning the conductive material layer 150′ formed on the substrate 110 to overlap with a middle portion of the semiconductor material layer 130′.

Referring to FIG. 5, a first insulating layer 140 may be formed by etching the insulating material layer 140′, using the gate electrode 150 as an etch mask. The gate electrode 150 and the first insulating layer 140 may have the substantially same planar shape. Portions of the semiconductor material layer 130′ that are not overlapped by the gate electrode 150 are exposed to an outside through the process described above.

A dry etching method may be used as the method of patterning the insulating material layer 140′. The buffer layer 120 may be prevented from being etched by controlling an etching gas and etching time.

A semiconductor pattern 130 may be formed by injecting N-type or P-type impurities into the semiconductor material layer exposed to the outside, using the first insulating layer 140 and the gate electrode 150, which are sequentially formed, as a mask.

When an N-type TFT is manufactured, V-group impurity ions of P, As, Sb, or the like may be injected into the semiconductor material layer. When a P-type TFT is manufactured, III-group impurity ions of B, Al, Ga, In, or the like may be injected into the semiconductor material layer.

An active region 130a into which impurities are not injected, due to being overlapped by the first insulating layer 140 and the gate electrode 150, and source and drain regions 130b and 130c into which impurities are injected by being respectively formed at both sides of the active region 130a, are formed through the process described above.

Referring to FIG. 6, an insulating material layer 160′ may be formed on the front surface of the substrate 110 having the semiconductor pattern 130 formed thereon. The insulating material layer 160′ may be formed with an organic insulating layer having a photosensitive characteristic. Subsequently, a mask (not shown) may be placed above the substrate 110 having the insulating material layer 160′ formed thereon.

Referring to FIG. 7, a second insulating layer 160 may be formed by patterning the insulating material layer 160′ to include first and second contact holes H1 and H2 through which portions of the respective source and drain regions 130b and 130c are exposed. The second insulating layer 160 including first and second contact holes 141 and H2 may be formed by a photo process using a mask.

The second insulating layer 160 having the first and second contact holes H1 and H2 may be formed through the photo process in which an etching gas is not used. Accordingly, the second insulating layer 160 does not undergo a reaction with any etching gas, the roughening of the surface of the second insulating layer 160 may be minimized.

Accordingly, the second insulating layer 160 may have no influence on the shapes of source and drain electrodes 170a and 170b formed through a subsequent process.

Referring to FIG. 8, the source and drain electrodes 170a and 170b may be formed on the substrate 110 having the second insulating layer 160 formed thereon to be respectively coupled to the source and drain regions 130b and 130c of the semiconductor pattern 130 through the first and second contact holes H1 and H2.

In the TFT 100 according to this embodiment, the surface roughness of the second insulating layer 160 formed with the organic insulating layer may be minimized. The metal resistance of the source and drain electrodes 170a and 170b formed through a subsequent process may be minimized, thereby improving characteristics of the TFT 100.

Further, in the TFT 100 according to this embodiment, the second insulating layer 160 including the first and second contact holes H1 and H2 may be directly formed through the photo process, such that it is possible to omit an etching process for forming contact holes, thereby simplifying the manufacturing process of the TFT 100.

Hereinafter, an application example of a flat panel display device to which the

TFT described above is applied will be described.

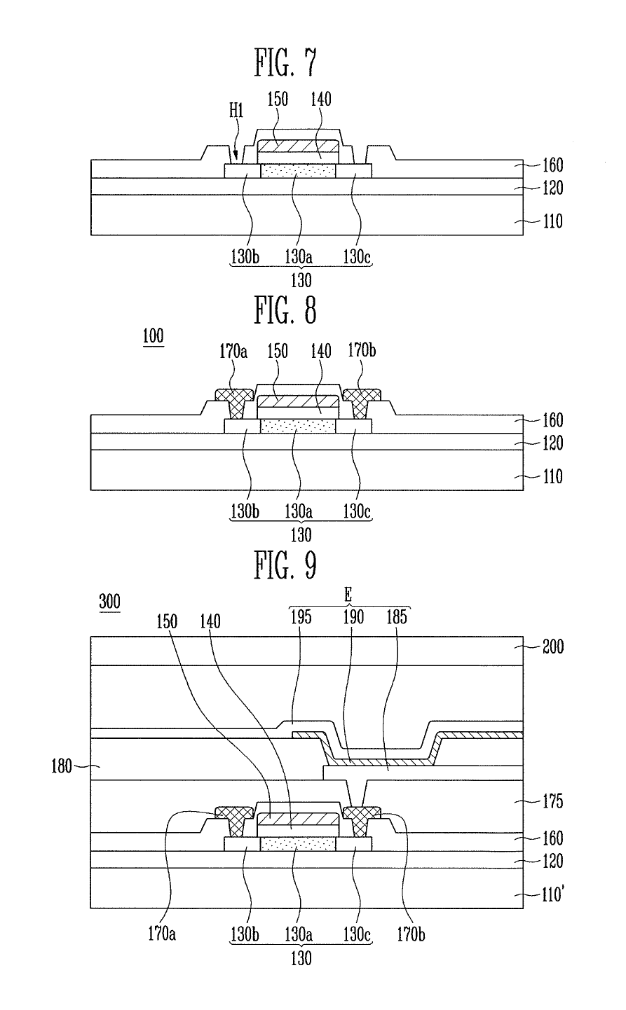

FIG. 9 illustrates a sectional view schematically depicting a flat panel display device according to an embodiment. Here, components identical to those of the aforementioned embodiment are designated by like reference numerals, and their detailed descriptions will not be repeated. In addition, differences of this embodiment from the aforementioned embodiment will be mainly described.

Referring to FIG. 9, the flat panel display device 300 including the TFT according to this embodiment is an organic light emitting display device, and may include a buffer layer 120 formed on a first substrate 110′; a semiconductor pattern 130 configured to include an active region 130a formed on the buffer layer 120, and source and drain regions 130b and 130c opposite to each other at both sides about the active region 130a; a first insulating layer 140 overlapped with the active region 130a on the semiconductor pattern 130; a gate electrode 150 formed on the first insulating layer 140; a second insulating layer 160 formed on the gate electrode 150 to include contact holes through which portions of the respective source and drain regions 130b and 130c are exposed; and source and drain electrodes 170a and 170b formed on the second insulating layer 160 to be respectively coupled to the source and drain regions 130b and 130c through the contact holes.

The flat panel display device 300 may further include a third insulating layer 175 formed to include a contact hole through which a portion of the drain electrode 170b is exposed on the first substrate 110′ having the source and drain electrodes 170a and 170b formed thereon; a first electrode 185 formed on the third insulating layer 175 to be electrically coupled to the drain electrode 170b through the contact hole; a pixel defining layer 180 configured to have an opening through which a portion of the first electrode 185 is exposed; an organic emission layer 190 formed on the pixel defining layer 180; and a second electrode 195 formed on the pixel defining layer 180 including the organic emission layer 190.

The first and second electrodes 185 and 195 and the organic emission layer 190 formed therebetween may constitute an organic light emitting diode E.

The penetration of external oxygen and moisture into the organic light emitting diode E may be prevented by providing a second substrate 200 which is opposite to the first substrate 110′ and seals the first substrate 110′.

A low or high molecular organic layer may be used as the organic emission layer 190. When the low molecular organic layer is used, the organic emission layer 190 may be formed by stacking, into a single- or multi-layered structure, a hole injection layer (HIL), a hole transport layer (HTL), an emission layer, an electron transport layer (ETL), an electron injection layer (EIL), or the like.

The first electrode 185 may act as an anode electrode, and the second electrode 195 may act as a cathode electrode. The polarities of the first and second electrodes 185 and 195 may be opposite to each other.

When the flat panel display device is a bottom emission type flat panel display device in which an image is displayed in the direction of the first substrate 110′, the first electrode 185 may be provided as a transparent electrode, and the second electrode 195 may be provided as a reflective electrode. The first electrode 185 may be formed of ITO, IZO or In₂O₃ having a high work function, and the second electrode 195 may be formed of a metal having a low work function, i.e., Ag, Mg, Al, Pt, Pd, Au, Ni, Ir, Nd, Cr, Li, Ca, or the like.

When the flat panel display device is a top emission type flat panel display device in which an image is displayed in the direction of the second electrode 195, the first electrode 185 may be provided as a reflective electrode, and the second electrode 195 may be provided as a transparent electrode.

When the flat panel display device is a both surface-emission type flat panel display device, both the first and second electrodes 185 and 195 may be provided as transparent electrodes.

The first and second electrodes 185 and 195 may be formed of the materials described above, or, in other implementations, may be formed of a conductive organic material or a conductive paste including conductive particles such as Ag, Mg or Cu. When the conductive paste is used, printing may be performed using an inkjet printing method. The conductive paste may be formed as an electrode by performing heat treatment after the printing.

In the flat panel display device 300, the first insulating layer 140 may be formed as an inorganic insulating layer. The first insulating layer 140 may be removed on the first substrate 110′ through an etching process using the gate electrode 150 as an etch mask after the gate electrode 150 is formed on the first substrate 110′. Thus, the first insulation layer 140 may be present only below the gate electrode 150 and may not be present on the source and drain regions 130b and 130c of the semiconductor pattern 130.

The second insulating layer 160 may be formed with an organic insulating layer having a photosensitive characteristic. The second insulating layer 160 may be formed to include contact holes through which portions of the respective source and drain regions 130b and 130c are exposed on the first substrate 110′.

The second insulating layer 160 may be formed with the organic insulating layer having the photosensitive characteristic. Accordingly, the second insulating layer 160 may be patterned through only a photo process using a mask to include the contact holes through which portions of the respective source and drain regions 130b and 130c are exposed.

The second insulating layer 160 is formed through the photo process. Accordingly, the second insulating layer 160 may not undergo a reaction with an etching gas used in a dry etching process. Thus, the roughness of the surface of the second insulating layer 160 may be minimized.

The surface roughness of the second insulating layer 160 may be minimized.

Accordingly, the second insulating layer 160 may have no influence on the shapes of the source and drain electrodes 170a and 170b formed on the second insulating layer 160 through a subsequent process, thereby implementing the low resistance of metal. Further, the second insulating layer 160 may have a low dielectric constant. Accordingly, parasitic capacitance between the electrodes may be minimized, thereby improving characteristics of the TFT.

The third insulating layer 175 may be formed on the first substrate 110′, using an organic or inorganic insulating layer. For example, the third insulating layer 170 may be formed as an inorganic insulating layer or as a complex of inorganic and organic insulating layers.

In the flat panel display device 300, the organic emission layer 190 and the second electrode 195 may be foamed on the first electrode 185 electrically coupled to the drain electrode 170b to constitute the organic light emitting diode E. The organic light emitting diode E may emit light with a luminance corresponding to driving current supplied from the TFT.

By way of summation and review, a TFT includes a gate electrode coupled to a gate line for supplying a scan signal, a source electrode coupled to a data line for supplying a signal to be applied to a pixel electrode, a drain electrode opposite to the source electrode, and a semiconductor layer electrically coupled to the source and drain electrodes.

The gate electrode and the source/drain electrode of the TFT are insulated from each other through an insulating layer formed therebetween. The gate electrode and the semiconductor layer of the TFT may also be insulated from each other through an insulating layer formed therebetween.

Source and drain electrodes in a TFT may be respectively coupled to source and drain regions included in a semiconductor layer through through-holes formed in an insulating layer. In a general process, the through-holes may be formed through an etching process of the insulating layer.

An organic layer may be applied to the insulating layer. If a dry etching process were to be performed on the insulating layer in order to form the through-holes in the insulating layer, the organic layer could reacts with a gas plasma, and the roughness of the surface of the insulating layer could be increased.

If a metal layer (source and drain electrodes) were to be formed on the surface of such an insulating layer through a subsequent process, the resistance of the metal layer could be increased due to the influence of the roughened insulating layer on the shape thereof. Hence, the metal layer may not properly perform the function of the source and drain electrodes, and characteristics of the TFT may be deteriorated.

According to the embodiments, the insulating layer made of an organic insulating material may be formed between the gate electrode and the source and drain electrodes, thereby improving characteristics of the TFT. An organic layer may be applied to the insulating layer formed between the gate electrode and the source/drain electrode in the TFT in order to perform the simplification of a process and to ensure flexibility when the insulating layer is applied to a flexible display. An organic layer may have a low dielectric constant. Accordingly, a high-speed response and high accuracy of the TFT may be provided by minimizing parasitic capacitance between the electrodes.

Further, the organic insulating material may be directly patterned, thereby forming the contact holes through which the respective source and drain regions are exposed. Accordingly, it may be possible to simplify the manufacturing process of the TFT.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope thereof as set forth in the following claims.

What is claimed is:

1. A thin film transistor (TFT), comprising:
a substrate;
a semiconductor pattern on the substrate, the semiconductor pattern including an active region, and source and drain regions opposite to each other at respective sides of the active region;
a first insulating layer on the active region;
a gate electrode on the first insulating layer, the gate electrode overlapping the active region;
a second insulating layer on a front surface of the substrate having the gate electrode formed thereon, the second insulating layer including contact holes through which portions of the respective source and drain regions are exposed; and
source and drain electrodes formed on the second insulating layer, the source and drain electrodes being respectively coupled to the source and drain regions through the contact holes.

2. The TFT as claimed in claim 1, wherein the second insulating layer includes an organic insulating material.

3. The TFT as claimed in claim 1, wherein the first insulating layer and the gate electrode have a same planar area, and completely overlap each other.

4. The TFT as claimed in claim 1, wherein the first and second insulating layers include different materials from each other.

5. The TFT as claimed in claim 4, wherein the first insulating layer includes an inorganic insulating material.

6. A method of manufacturing a TFT, the method comprising:
providing a substrate;
forming, on the substrate, a semiconductor pattern including an active region, and source and drain regions opposite to each other at respective sides of the active region;
forming a first insulating layer and a gate electrode to overlap the active region;
depositing an organic insulating material layer on a front surface of the substrate having the gate electrode formed thereon;
providing a mask above the substrate having the organic insulating material layer formed thereon;
forming a second insulating layer by patterning the organic insulating material layer to include contact holes through which portions of the respective source and drain regions are exposed, using the mask; and
forming source and drain electrodes respectively coupled to the source and drain regions through the contact holes.

7. The method as claimed in claim 6, wherein forming the first insulating layer and the gate electrode further includes:
forming an insulating material layer on the semiconductor pattern;
depositing a metal layer on the insulating material layer;
forming the gate electrode by patterning the metal layer to overlap the active region; and
forming the first insulating layer by removing the insulating material layer except for a portion that overlaps with the gate electrode, using the gate electrode as an etch mask.

8. The method as claimed in claim 6, wherein the first insulating layer and the gate electrode have a same planar area, and completely overlap each other.

9. The method as claimed in claim 6, wherein the first and second insulating layers include different materials from each other.

10. The method as claimed in claim 6 wherein the first insulating layer includes an inorganic insulating material.

11. A flat panel display device, comprising:
a first substrate on which an organic light emitting diode including a first electrode, an organic emission layer and a second electrode, and a TFT for controlling an operation of the organic light emitting diode are located; and
a second substrate opposite to the first substrate,
wherein the TFT includes:
a semiconductor pattern on the first substrate, the semiconductor pattern including an active region, and source and drain regions opposite to each other at respective sides of the active region;
a first insulating layer on the active region;
a gate electrode on the first insulating layer, the gate electrode overlapping the active region;
a second insulating layer on a front surface of the first substrate having the gate electrode formed thereon, the second insulating layer including first contact holes through which portions of the respective source and drain regions are exposed;
source and drain electrodes on the second insulating layer, the source and drain electrodes being respectively coupled to the source and drain regions through the first contact holes; and
a third insulating layer on the source and drain electrodes, the third insulating layer including a second contact hole through which a portion of the drain electrode is exposed, and
wherein the drain electrode and the first electrode are electrically coupled to each other through the second contact hole.

12. The flat panel display device as claimed in claim 11, wherein the second insulating layer includes an organic insulating material.

13. The flat panel display device as claimed in claim 11, wherein the first insulating layer and the gate electrode have a same planar area, and completely overlap each other.

14. The flat panel display device as claimed in claim 11, wherein the first and second insulating layers include different materials from each other.

15. The flat panel display device as claimed in claim 11, wherein the first insulating layer includes an inorganic insulating material.

16. The flat panel display device as claimed in claim 11, wherein the third insulating layer is made of at least one selected from an inorganic insulating material and an organic insulating material.
